(19) United States
(12) Patent Application Publication
(10) Pub. No.: US 2022/0216321 A1
(43) Pub. Date: Jul. 7, 2022

(54) Redox Gating Materials and Methods of Making and Using the Same

(71) Applicants: UCHICAGO ARGONNE, LLC, Chicago, IL (US); THE UNIVERSITY OF CHICAGO, Chicago, IL (US)

(72) Inventors: Wei Chen, Naperville, IL (US); Matthew Tirrell, Chicago, IL (US); Hua Zhou, Naperville, IL (US); Le Zhang, Darien, IL (US); Hui Cao, Darien, IL (US); Changjiang Liu, Woodridge, IL (US)

(21) Appl. No.: 17/248,001

(22) Filed: Jan. 4, 2021

(51) Int. Cl. H01L 29/51; H01L 29/786; H01L 29/24

(52) U.S. Cl. CPC H01L 29/51; H01L 29/24; H01L 29/7869

(57) ABSTRACT

Redox gating, intrinsically apart from conventional electrolyte gating, combines reversible redox functionalities with common ionic electrolyte moieties to engineer charge transport for power efficient phase control. A colossal sheet carrier density modulation beyond 10¹⁶/cm² as well as up to thousand durable cycling can be reached at the subvolt regime in archetypical functional oxide thin films without unbridled perturbations from ionic defects, which include either cation/anion vacancy or ionic intercalated species like proton. Besides, the redox gating represents a simply and practical way to decouple the electrical and structural phase transitions, improving the device longevity and operation response time. The redox gating works for a wide variety of materials regardless of its crystallinity or crystallographic orientation, including all other functional heterostructures and low-dimensional quantum materials composed of sustainable elements.

### STATEMENT OF GOVERNMENT SUPPORT

This invention was made with government support under Contract No. DE-AC02-06CH11357 awarded by the United States Department of Energy to UChicago Argonne, LLC, operator of Argonne National Laboratory. The government has certain rights in the invention.

### BACKGROUND

### Field of the Disclosure

The disclosure relates to redox gating materials and methods of using the same; and more particularly to redox gating materials and methods of using the same that can allow for reversible transformation between electronic states at low sub-volt gate voltages in functional field effect thin film devices.

### BRIEF DESCRIPTION OF RELATED TECHNOLOGY

Ionic gating at an electrolyte-electrode interface is known to form an electric double layer (EDL) that can induce immense carrier concentrations on the order of 10¹⁴-10¹⁵/cm². At these levels, one can drive electronic, magnetic, optical, and topological phase transitions of materials, expanding the use of field effects to gain control over the myriad of ground states at the interfaces of functional materials.

Ionic gating imposes fundamental limits, either in the control or in the manipulation of gated materials. The carrier distribution in the case of electrostatic gating can be described by the Thomas-Fermi model, where the carrier accumulation near the EDL interface drops off rapidly with the field penetration. Changes in the sub-volt regime do not greatly affect the concentration of carriers. The carrier density can reach about 5×10¹⁴/cm², but only when the field nears the breakdown limit of the electrolyte, assuming the channel material remains electrochemically stable. This carrier density can be surpassed with ionic gating since ions and electrons cross the interface, with electrochemistry playing a dominant role in the behavior at high voltages (>1.5-2 V). Carrier densities as high as 4×10¹⁶/cm² can be achieved through oxygen vacancy formation or proton intercalation. However, electrochemical processes or radical surface adsorbates can lead to unwanted disorder and induce unexpected defects within the crystal or chemical structures that will eventually deteriorate the gated material. Furthermore, there remains some uncertainty with regard to controlling mechanism of the gating-induced phase transitions. The assumption of a purely electrostatic effect based on electron or hole doping (i.e., conventional gating) was shown to be false through extensive characterization of the EDL interface and depth-resolved studies of gated oxide thin films. Ionic motion driven by specific electrochemical interactions has since been regarded as commonplace and inevitable in the ionic gating process. Practically speaking, ionic gating is seen to be detrimental to the development of many EDL-based technologies as the gating material cannot be easily controlled or reliably reconfigured due to the irreversible chemical changes that occur. In brief, ionic gating by either the electrostatic or ion-doing process remains far from ideal.

### SUMMARY

The disclosure provides redox gating materials and methods, which integrate reversible redox functionalities to engineer charge transport for reversible transformation between electronic states at low sub-volt gate voltages in functional field-effect thin film devices.

### BRIEF DESCRIPTION OF THE DRAWINGS

FIG. 1A is a schematic illustration of the operative mechanism of conventional ionic gating;

FIG. 1B is a schematic illustration of the operative mechanism of redox gating;

FIG. 2 is a graph summarizing the tuning of transport properties of functional materials by ionic gating as a function of gate voltages;

FIG. 3A is a schematic of the molecular structures and abbreviation names of gating materials of embodiments of the disclosure;

FIG. 3B is a graph comparing the redox processes and working voltage range of three types of redox gating materials in accordance with embodiments of the disclosure;

FIG. 4A is a graph of the normalized resistive modulation as a function of gate voltages for three types of redox gating materials in accordance with embodiments of the disclosure;

FIG. 4B is a graph showing the recyclability of resistivity modulation at a fixed alternating gate voltage for three types of redox gating materials in accordance with the disclosure, and a comparison with conventional ionic gating;

FIG. 5A is a graph of the lattice structural evolution of WO₃ thin film as a function of gate voltages for both conventional ionic gating and redox gating, probed by in situ thin film X-ray diffraction;

FIG. 5B is a graph showing the lattice constant changes as a function of gate voltages for conventional ionic gating and redox gating;

FIG. 5C is a graph showing the chemical state evolution of WO₃ thin film as a function of gate voltages for both ionic gating and redox gating, probed by in situ X-ray absorption near edge spectroscopy (XANES);

FIG. 5D is a differential XANES spectral revealing subtle variation of chemical states and local coordination of WO₃ thin film upon both ionic gating and redox gating processes;

FIG. 6A is a graph of the temperature-dependent resistivity FcRG-gated LaNiO₃ (LNO) film at different gate voltages;

FIG. 6B is a graph of the gate voltage-dependent resistivity of FcRG-gated LNO film at 10K. The inset shows the variation of the resistivity for V_{G}≤0.7 V;

FIG. 6C is a graph of the Hall voltages of FcRG-gated LNO film at 10K as a function of magnetic fields. The inset shows the geometry of the device used in electrical transport measurements (Four-point-probe resistivity measurement and Hall measurement);

FIG. 6D is a graph of the gate voltage-dependent Hall densities of FcRG-gated LNO film. The dashed lines are provided only as a visual guide;

FIG. 7A is the (002) Bragg peak intensities of FcRG-gated LNO film as a function of gate voltages;

FIG. 7B is graphs showing a lattice expansion of FcRG-gated LNO film (top) and such a lattice expansion is revisable (bottom);

FIG. 7C is a graph of the lattice constant FcRG-gated LNO film as a function of gate voltages; the short, dashed line is supplied only as a visual guide;

FIG. 7D is a schematic of the electron injection-induced lattice expansion and band structure change of FcRG-gated LNO film;

FIG. 8A is the Ni K-edge XANES spectra of references and FcRG-gated LNO film at V_{G}=0 V and 1.5 V. The inset is the first derivative XANES spectra of FcRG-gated LNO at V_{G}=0V and 1.5V;

FIG. 8B is the Ni K-edge XANES spectra of FcRG-gated LNO film at V_{G}=0 V, 0.3 V, 0.6 V and 0.7 V. The inset is the first derivative XANES spectra of FcRG-gated LNO film at V_{G}=0 V and 0.7 V;

FIG. 8C is a graph showing the evolution of Ni valence in FcRG-gated LNO film at different gate voltages. The dashed line is provided only as a visual guide;

FIGS. 9A-9C are graphs illustrating the gating process of VO₂ films using (A) traditional DEME-TFSI electrolytes, and (B) ILG, (C) FcRG redox gating materials in accordance with embodiments of the disclosure, respectively;

FIGS. 9D-9F are graphs of the transport measurements of VO₂ films using the corresponding gating materials of FIGS. 9A-9C, showing suppression of the temperature driving metal-insulator transition in VO₂ films;

FIG. 10A is a graph of gate voltage dependence of the normalized resistance of VO₂-film using DEME-TFSI, ILG, and FcRG gating materials in accordance with embodiments of the disclosure, measured at 300K with the sweep rate of 0.5 mV/s, indicating a series of reversible phase transitions. For DEME-TFSI, the gating voltage was swept from −2.0 V to 2.0 V, while for ILG and FcRG, the gating voltage was swept from −0.8 V to 0.8 V. Arrows show the direction of resistance changes in the process of voltage sweeping;

FIG. 10B is a graph of the durability of resistivity modulation at alternating gating voltages for the three types of gating materials of FIG. 8A;

FIG. 11A is a schematic illustration of the epitaxial geometric relationships between VO₂ thin film and A12O₃ substrate;

FIG. 11B is the (020) specular reflection of VO₂ thin films gated by DEME-TFSI, ILG, and FcRG gating materials at different gate voltages at room temperature;

FIG. 11C is a graph showing the temperature dependence of the specular reflection (020) of the pristine VO₂ thin film;

FIG. 11D is a graph showing the temperature dependence of the (020) specular reflection of VO₂ thin films gated by ILG. The left short-dashed line indicates tetragonal phase, and the right short-dashed line indicates monoclinic phase;

FIG. 11E is a graph of the first derivative of V K-edge XANES spectral for different ionic liquids and gate voltages;

FIG. 12A is a graph of lattice structure changes of VO₂ thin films gated by FcRG, when the gating voltage is greater than the critical gating voltage;

FIG. 12B is a graph showing that at the elevated temperature, the lattice structure of VO₂ thin film under applying a gating voltage is the same as that of pristine film;

FIG. 12C is a graph showing the lattice constant as a function of temperature;

FIG. 12D is a graph showing the (220) spacing of as a function of temperature;

FIG. 13A is a (020) spectral reflection of VO₂ thin film verse temperature in pristine film;

FIG. 13B is a (020) spectral reflection of VO₂ thin film verses temperature after applying ILG gating;

FIG. 13C is a (220) non-specular reflection of VO₂ thin film verses temperature in pristine film;

FIG. 13D is a (220) non-specular reflection of VO₂ thin film verses temperature after applying ILG gating;

FIG. 14 is a schematic illustration of the synthetic route of poly(1-ethyl-4-vinyl pyridine-1-ium bromide)-co-poly(ferrocenylmethyl methacrylate) (PQ4VP-co-PFcMMA) copolymers;

FIG. 15 is the ¹H NMR spectrum of PQ4VP-co-PFcMMA copolymers;

FIG. 16 is a schematic illustration of the synthetic route of poly(3-[6-(2,5-dimethylthiophen-3-yl)hexyl]-1-methyl-1H-imidazol-3-ium bromide) (PTImBr) polymers;

FIG. 17 is the ¹H NMR spectrum of poly[3-(6-bromohexyl)thiophene] (P3BHT) precursor polymers;

FIG. 18 is the ¹H NMR spectrum of poly(3-[6-(2,5-dimethylthiophen-3-yl)hexyl]-1-methyl-1H-imidazol-3-ium bromide) (PTImBr) polymers; and

FIG. 19 is the ¹³C NMR spectrum of PTImBr polymers.

### DETAILED DESCRIPTION

In accordance with embodiments, redox gating materials in accordance with the disclosure can include a combination of reversible redox functionalities with ionic electrolyte moieties. Redox gating materials of the disclosure can allow for a carrier density modulation beyond 10¹⁶/cm² and improved control on the transformation between electronic states. The resulting transitions can be highly reversible and occur within the sub-volt regime in functional field effect transistors (FETs) in accordance with embodiments of the disclosure. Redox gating can advantageously break the limits of conventional ionic gating.

In accordance with embodiments, the redox gating material can be a redox agent alone. For example, the redox gating material can consist of the redox agent. In accordance with embodiments, a redox gating material can include an admixture of a transition metal salt or a redox agent with one or more ionic electrolytes. In embodiments, the variable valence transition metal salt can include one or more of Cu ions, Fe ions, V ions, Co ions, Ni ions, and their corresponding coordination ions. In embodiments, the redox agent can include redox-active functional groups selected from the group consisting of ferrocene, viologen, quinone, TEMPO, thiophene, benzophenone, ferrocyanide, ferricyanide, and combinations. In embodiments, the redox gating material can be in a liquid state or in a gel state. For example, in embodiments, the redox gating material can be an ionogel film.

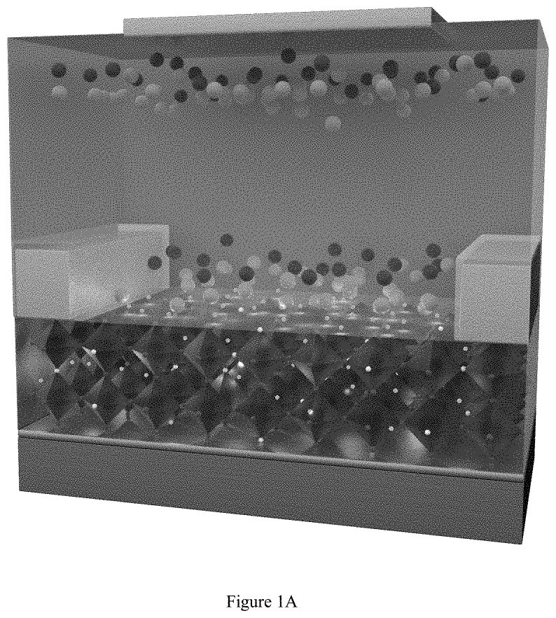

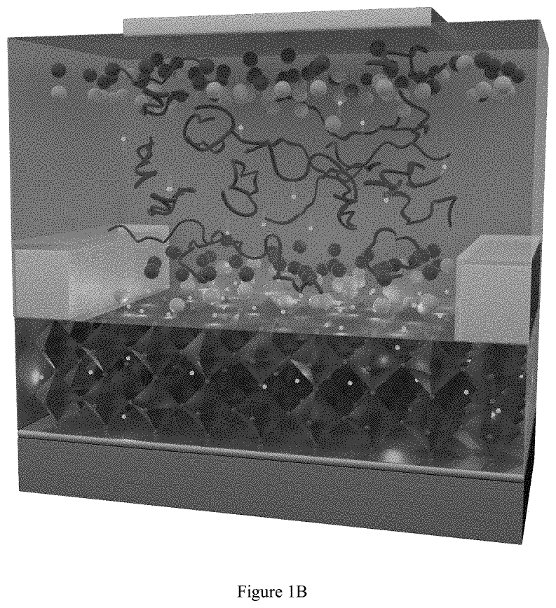

Referring to FIGS. 1A and 1B, redox gating in accordance with the disclosure has an intrinsically distinct mechanism from conventional ionic gating. In conventional ionic gating (FIG. 1A), cations and anions within the electrolyte move toward their respective electrodes after the application of a gate voltage, forming a sub-nanometer-gap EDL atop a functional thin film. Capacitive cycling takes place in the IL up to 4-5 V, which is the electrochemical breakdown limit of most electrolytes. The electrostatic effect is universal (i.e., the FET channel is material independent) once the gate voltage is applied. In contrast, ionic gating only occurs when the interfacial EDL field strength is large enough (typically greater than 1.5-2 V and exceeding 10 MV/cm) to drive electrochemical processes in the functional thin film but prior to breakdown. Ionic gating is a field-dependent process but always coupled with electrostatic gating, and it can also be highly channel material dependent. Only in very few cases does the motion of ions in channel materials appear inactive or utterly immobile even if the interfacial EDL field is considerable. In redox gating (FIG. 1B), the gating medium is composed of redox-active functional groups and able to release a large quantity of free electrons or holes via redox reactions; the carriers are injected into the gated materials to induce dramatic changes in electronic state even at low gate voltages. In short, redox gating takes place entirely within the electrochemical stability window while the molecular redox processes occur within the gating medium, bypassing the issues plaguing other methods like ionic gating.

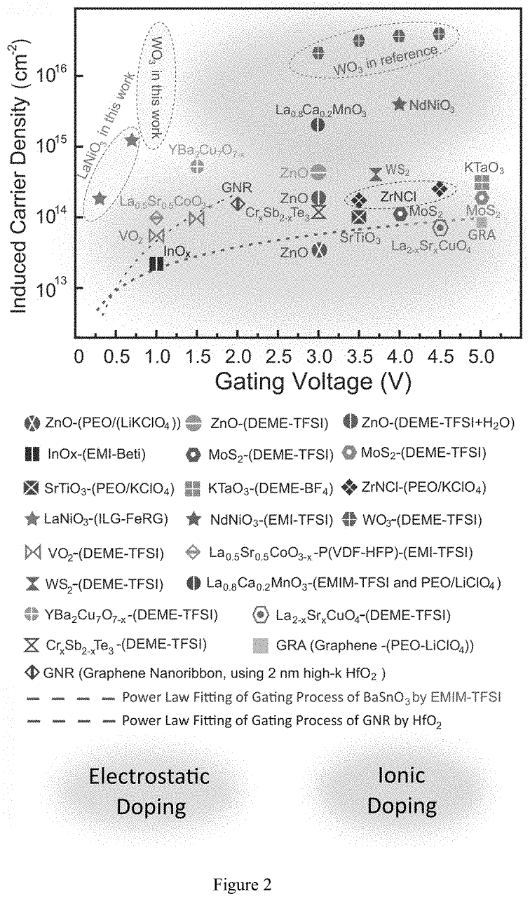

FIG. 2 summarizes some of the recent reports describing modulated carrier densities as a function of gate voltage for a variety of functional materials including perovskite oxides, optoelectronic semiconductors, topological insulators, transition metal dichalcogenides and graphene-based 2D materials. For EDL gating, two distinct regimes can be identified. Electrostatic doping spans across the voltage range as long as the breakdown limit of the gating media is not exceeded. In FIG. 2, two power-law trends for the carrier density-voltage relationship were overlaid, one from a study of BaSnO₃ gated by 1-ethyl-3-methylimidazolium bis(trifluoromethylsulfonyl)imide (EMIM-TFSI) and the other from the high-k ferroelectric HfO₂ and a graphene nanoribbon. Electrostatic doping was confirmed for both systems. The two trends represent estimates of the magnitude of carrier modulation. Carrier densities no greater than 5×10¹⁴/cm² can be attributed to electrostatic effects alone. The purple-shaded region shows the range for ionic doping as induced by electrochemical reactions in gated materials, which can exceed densities of 10¹⁵/cm².

To date, the maximum reported carrier density induced by EDL gating is 4×10¹⁶/cm² for a WO₃ thin film gated at 4.5 V with diethylmethyl(2-methoxyethyl)ammonium bis(trifluoromethylsulfonyl)imide (DEME-TFSI) at low temperature. In this case, proton intercalation rather than electrostatic carrier accumulation is responsible for the change in transport properties. In comparison, the induced room-temperature carrier densities in a redox-gated WO₃ transistor in accordance with the disclosure (example 1) was estimated to be 10¹⁵-10¹⁶/cm² between 0.8 and 1.2 V (oval in the left upper corner) after analysis of the gate current as a function of voltage. Hall effect measurements could offer direct quantification, but an accurate determination of the induced carrier density in a redox-gated WO₃ transistor is non-trivial. Without intending to be bound by theory, it is believed that conduction in the gated film occurs through hopping via the impurity sites, leading to a tiny Hall voltage buried in the background noise; the Hall signal can be further reduced by polarons formed in the gated thin film. To precisely quantify the induced carrier density, metallic LaNiO₃ (LNO) was gated as described in detail in example 2. A carrier density of 1.8×10¹⁴-1.3×10¹⁵/cm² was induced at voltages of 0.3-0.7 V (stars on the left upper corner); additional details are presented in Table 1, below.

TABLE 1

| | | | INDUCED | |
|---|---|---|---|---|
| FUNCTIONAL | | GATING | CARRIER | DOMINANT |
| OXIDE FILMS | ELECTROLYTE | VOLTAGE (V) | DENSITY (CM⁻²) | MECHANISM |
| INO_{X} | EMI-BETI | 1 | 2.2 × 10¹³ | ELECTROSTATIC |
| ZNO | PEO-LIKCLO₄ | 2-3 | 4.2 × 10¹³-4 × 10¹⁴ | ELECTROSTATIC |
| | OR DEME-TFSI | | | |
| ZNO | DEME-TFSI + H₂O | 3 | 2 × 10¹⁴ | HYDROGEN |
| | | | | INJECTION |
| SRTIO₃ | PEO-KCLO₄ | 2.5-3.5 | 1.0 × 10¹³-1.0 × 10¹⁴ | ELECTROSTATIC |
| ZRNCL | PEO-KCLO₄ | 3.5-4.5 | 1.7 × 10¹⁴-2.5 × 10¹⁴ | ELECTROSTATIC |
| KTAO₃ | DEME-BF₄ | 5 | 3 × 10¹⁴ | ELECTROSTATIC |
| MOS₂ | DEME-TFSI | 2-5 | 1 × 10¹⁴-3 × 10¹⁴ | ELECTROSTATIC |
| YBA₂CU₇O_{7-X} | DEME-TFSI | 1.5 | 5.2 × 10¹⁴ | ELECTROSTATIC |
| | | | | (WEAKLY |
| | | | | ELECTROCHEMICAL) |
| LA_{2-X}SR_{X}CUO₄ | DEME-TFSI | 4.5 | 7 × 10¹³ | ELECTROSTATIC |
| LA_{0.8}CA_{0.2}MNO₃ | EMIM-TFSI AND | 3 | 2 × 10¹⁵ | ELECTROSTATIC AND |
| | PEO/LICLO₄ | | | ELECTROCHEMICAL |
| VO₂ | DEME-TFSI | 1-1.5 | 6.25 × 10¹⁴-9.37 × 10¹⁴ | ELECTROSTATIC |
| VO₂ | HMIM-TFSI | ~1.8 | — | OXYGEN VACANCY |
| VO₂ | DEME-TFSI | ~1.5 | — | HYDROGEN |
| | WITH H₂O | | | INJECTION |
| WS₂ | DEME-TFSI | 3.7 | 4 × 10¹⁴ | ELECTROSTATIC |
| CR_{X}SB_{2-X}TE₃ | DEME-TFSI | 3 | 1.2 × 10¹⁴ | ELECTROSTATIC AND |
| | | | | ELECTROCHEMICAL |
| WO₃ | DEME-TFSI | 3-4.5 | 2.2 × 10¹⁶-4 × 10¹⁶ | OXYGEN VACANCY |
| | | | | AND HYDROGEN |
| | | | | INJECTION |
| TA(4 NM)/PT(3 | GDO_{X} | 4 | 6.25 × 10¹⁵ | HYDROGEN |
| NM)/CO(0.9 NM) | | | | INJECTION |
| GRAPHENE | GATE | 2 | 7.5 × 10¹³-2.25 × 10¹⁴ | ELECTROSTATIC |
| NANORIBBON | INSULATOR | | | |
| | WITH K = 16 | | | |
| NDNIO₃ | EMI-TFSI | 4 | 3 × 10¹⁵ | ELECTROSTATIC AND |
| | | | | ELECTROCHEMICAL |
| SRCOO_{3-Σ} | DEME-TFSI | 0-4 | — | OXYGEN VACANCY |
| | | | | AND HYDROGEN |
| | | | | INJECTION |
| LANIO₃ | FCRG | 0.3-0.7 | 1.8 × 10¹⁴-1.3 × 10¹⁵ | REDOX ELECTRON |
| (EMBODIMENT | | | | INJECTION |
| OF THE | | | | |
| DISCLOSURE) | | | | |
| WO₃ | FCRG, PTRG, | 0.8-1.2 | 1.7 × 10¹⁴-3.0 × 10¹⁶ | REDOX ELECTRON |
| (EMBODIMENT | CURG | | | INJECTION |
| OF THE | | | | |
| DISCLOSURE | | | | |

In accordance with embodiments, the redox gating materials can be used with a variety of channel materials, including, but not limited to, functional oxides and low-dimensional materials. For example, functional oxides can include one or more of WO₃, VO₂, LaNiO₃, NdNiO₃, Nd₁₋ₓSrₓNiO₂, and Pr₁₋ₓSrₓNiO₂. Low-dimensional materials can include, for example, one or more of Bismuth, MoS₂, HfS₂, and WSe₂.

In embodiments, redox gating materials of the disclosure can include a mixture of (a) transition metal salts with variable valency and/or redox agents containing redox-active functional groups and (b) ionic electrolytes. Redox gating materials of the disclosure exhibit a standard redox potential of −1V-1V. The ionic electrolytes can improve the conductivity of gating media and assist in the EDL formation at the topmost surface of functional materials to promote the carrier injection into the channel materials.

In embodiments, the variable valence transition metal salt can include one or more of Cu ions, Fe ions, V ions, Co ions, Ni ions, and their corresponding coordination ions. The metal salt could be present in an amount below the saturated concentration in electrolyte solutions.

Redox gating materials of the disclosure can include electrolyte solutions in a liquid state and ionogel films in a gel state. The electrolyte solutions and ionogel films can be prepared by dissolving one or more of redox agents in one or more of ionic electrolytes (e.g., ILs).

The redox gating material can be electron-injecting or hole-injecting.

In embodiments, the redox agent can include one or more of poly(ionic liquids) (PILs), which are polymers featuring redox-active functional groups and ionic liquid species in monomer repeating units, connected through a polymeric backbone to form a macromolecular architecture. The functional groups could ferrocene, viologen, quinone, TEMPO, thiophene, benzophenone, ferrocyanide, ferricyanide, and combinations. The ionic liquid species can include one or more of quaternary imidazolines, quaternary pyridines, ferrocenium, cobaltocenium, ferrocyanide, ferrocyanide, dicyanamide, bis(trifluoromethylsulfonyl)imide, and hexafluorophosphate, and combinations. The redox agent can include about 5% to about 85% by mole of the redox-active functional groups based on the total mole of the redox gating material.

The PILs can include conjugated PILs or metal-containing PILs.

The conjugated PIL can include polythiophene PIL, poly(quinone) PIL, poly(viologen) PIL, and combinations thereof. For example, polythiophene PIL can include one or more of 3,4-ethylenedioxythiophene, imidazole-functionalized thiophene monomers, and combinations. poly(quinone) PIL can include one or more of repeating quinone isomers, including benzoquinones, naphthoquinones, anthraquinone, phenanthraquinones, and combinations. poly(viologen) PIL can include one or more of conjugated bi-/multi-pyridyl groups, 1,1′-disubstituted-4,4′-bipyridiliums, and combinations.

The metal-containing PIL can include one or more of ferrocene-containing poly(ionic liquids), ferrocyanide-containing poly(ionic liquids), ferricyanide-containing poly(ionic liquids), and combinations. For example, ferrocene-containing poly(ionic liquids) can include one or more of ferrocenylenes, ferrocenylsilanes, pendant ferrocenes, and combinations.

For the redox gating material in a liquid state, the PIL can be present in the redox gating material in an amount of about 1 wt % to about 15 wt % based on the total weight of the redox gating material, while for the redox gating materials in a gel state, the PIL is a redox-active polymer present in an amount of at least about 15 wt % based on the total weight of the redox gating material. In embodiments, a redox gating material can be provided with 100 wt % PIL, such that the redox gating material consists of the redox agent. In other embodiments, redox gating materials consisting of the redox agent can include combinations of any of the redox agents disclosed herein. Without intending to be bound by theory, it is believed that the highly flexible and transferrable redox gating materials of the disclosure and their potential to manipulate the underlying materials without introducing structural or chemical change would advance sustainable materials usage and potentially leapfrog device design and implementation.

The ionic electrolyte can include one or more of 1-ethyl-3-methylimidazolium dicyanamide (EMIM-DCA), DEME-TFSI, EMIM-TFSI, and 1-Butyl-3-methylimidazolium dicyanamide (BMIM-DCA).

Redox gating materials of the disclosure can include an ionic electrolyte. The ionic electrolyte can be included in an amount of about 0 wt % to 99 wt %. For example, poly(viologen) PILs only without the addition of ionic electrolytes can be used as the hole-injecting redox gating materials.

A method of redox gating in accordance with the disclosure can include providing a channel and a redox gating material in accordance with embodiments of the disclosure and applying a gating voltage of about ±0.2 V to about ±1.5 V. Methods of redox gating in accordance with the disclosure can result in carrier densities of at least about 10¹⁴ cm² within a sub-volt regime. The methods of the disclosure advantageously provide for redox gating, which are beneficially capable of generating high carrier densities with low gating voltages, for example, even sub-volt gating voltages.

Without intending to be bound by theory, it is believed that redox gating can tune the carrier concentration of condensed channel materials by a low switching voltage without, in principle, altering the structural and chemical integrity. From a fundamental perspective, the enhanced reliability and durability of electronic phase control endowed by redox gating presents a wealth of opportunities for the investigation of phase transitions in strongly correlated materials. From an applied perspective, redox-gated transistors address problems arising from the reduced operating voltage of highly scaled CMOS. Redox gating also presents a promising opportunity to craft emergent functions of reconfigurable quantum materials that go far beyond what conventional semiconductor physics defines, as well as enable ultralow power device concepts that mimic synaptic switches in the brain.

### EXAMPLES

### Example 1

Redox gating materials in accordance with the disclosure were incorporated into a WO₃ thin film transistor. WO₃, a perovskite-type (ABO₃) insulator with vacant A sites and an unoccupied 5d⁰ conduction band, is a favorable candidate for electrical transport studies since it exhibits 5-6 orders of magnitude variation in resistivity when heavily electron doped and displays pronounced structural distortions whenever defect formation or ionic injection is involved in the gating process.

Three categories of redox gating media were designed and synthesized, comprised of the following ionic liquid solutions: (I) conjugated PILs, (II) metal-containing PILs, and (III) simple metal salts.

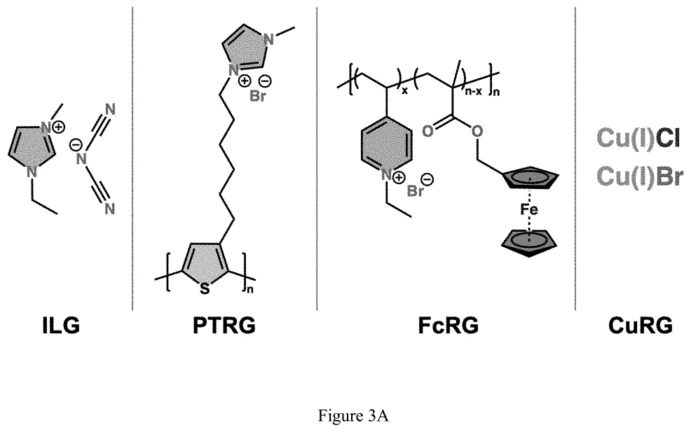

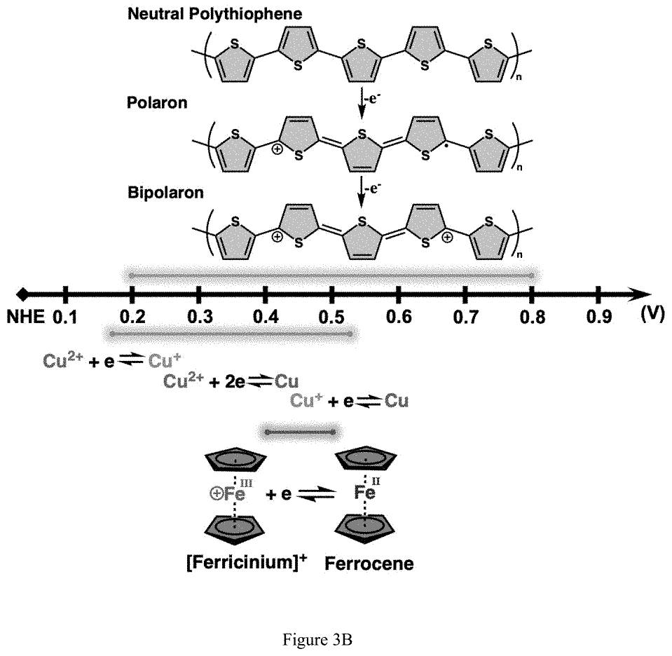

For synthesis of the gating media, imidazole-functionalized conjugated polythiophene PIL (type 1, designated as PTRG), ferrocene-containing PIL (type II, designated as FcRG), and copper(I) salt (type Ill, designated as CuRG) were dissolved into EMIM-DCA ILs, as shown in FIG. 3A. More details on the chemical structures are provided in the following section of Materials and Methods. As illustrated in FIG. 3B, the oxidation reactions of the conjugated polythiophene polymers occur in a broad potential range from 0.2 to 0.8 V via two irreversible electron transfer steps, ferrocene undergoes reversible one-electron oxidation to form ferrocenium at ˜0.4 V, and copper is able to reversibly convert between Cu⁺, Cu²⁺, and Cu below 0.6 V through three reactions. All the media release electrons through the redox process and inject electrons into the WO₃ channel with the aid of a modest EDL-induced electric field at the top of WO₃.

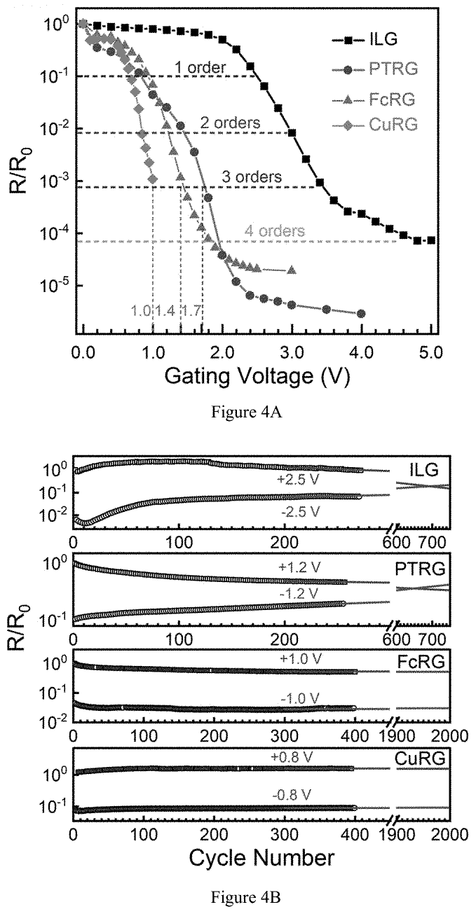

Referring to FIG. 4A, a WO₃ thin film channel in a lithographically patterned planar device becomes metallic at gate voltages well larger than 1.8 V when performing conventional ILG with EMIM-DCA. The eventual decrease in resistivity is mainly attributed to the generation of oxygen vacancies/proton injection. In contrast, the WO₃ sheet resistance drops by three orders of magnitude at 1.7 V for PTRG, 1.4 V for FcRG, and 1.0 V for CuRG. The contrast is most apparent at 2.0 V, where the resistivity changes by five orders of magnitude for PTRG while little change is observed for ILG. The critical redox gate voltage necessary to induce the metallic state is less than 1.0 V, which is exceptionally low when compared to the values reported in other ILG studies. It is also worth noting that the WO₃ sheet resistance can change by one order of magnitude when tuning the gate voltage between 0.8-1.0 V.

Referring to FIG. 4B, the resistance data upon switching WO₃ between the high and low resistance states was compared to measure the reversibility of the redox gated-IMT process. The irreversible polythiophene oxidation-reduction reactions lead to the eventual loss of resistance tunability when PTRG is cycled between ±1.2 V. The gap in resistance steadily decreases as the cycle number increases, and the two resistance states merge after ˜600 cycles. In contrast, the resistance gap stays constant (by over one order of magnitude) when the gate voltage alternates between ±1.0 V for FcRG and ±0.8 V for CuRG for at least 400 cycles. The extrapolated red and blue curves extend well past a thousand cycles, highlighting the reproducibility of the redox gating process. Few studies have demonstrated more than hundreds of gating cycles in their tests of durability. Due to the complicated multiple redox processes, Cu can deposit on WO₃ during CuRG gating, potentially contaminating the thin film and limiting practical applications. As for conventional ionic gating by ILG, a gate voltage of ±2.5 V is necessary to achieve a tunability similar to PTRG. The WO₃ sheet resistance fluctuates over the initial tens of cycles and then exhibits a behavior similar to PTRG because of occurrence of similar electrochemical reactions.

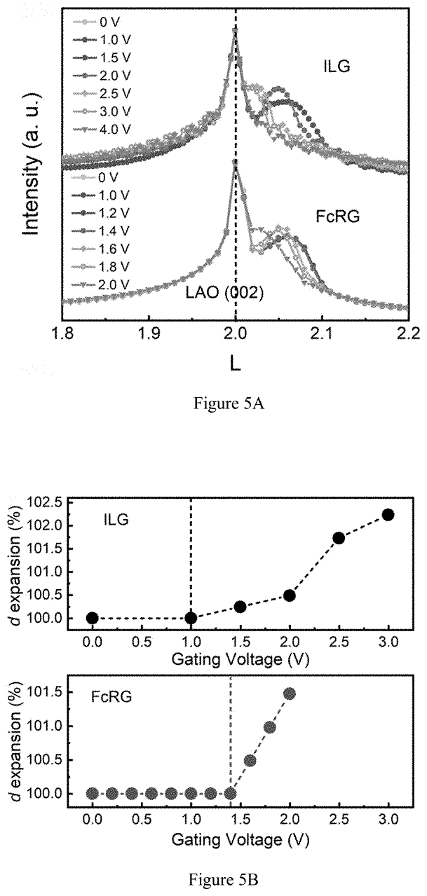

in situ synchrotron X-ray diffraction (XRD) experiments were performed in order to detect structural changes for conventional ILG gating (0 to 4.0 V) and for FcRG gating (0 to 2.0 V). The results show no changes in structure occur below 1.2 V for either medium, as evidenced by constant intensities and positions of the out-of-plane (002) peaks in FIG. 5A. The well-maintained lattice Laue fringes along the XRD curves also indicate negligible degradation in the surface roughness. For voltages near 1.4 V and higher, lattice expansion can be explicitly discerned in FIG. 5B, which is caused by the motion of oxygen ions (changes to the oxygen octahedra or lattice disorder) induced in both gating processes. The threshold gate voltage for electrochemically-induced lattice distortions is 1.3-1.4 V for WO₃. Structural analysis of half-order Bragg peaks (e.g., the (1.5 0.5 1.5) or the (0.5 0 1.5)), which are sensitive to both octahedral rotation and oxygen site occupancy, presents the same trend. in situ XRD then confirms that gating below 1.4 V results in little to no structural perturbations, indicating a pure carrier injection process. As presented in FIG. 5A, gating with FcRG renders a drop in resistance by three orders of magnitude at 1.4 V while little change is seen at this potential for ILG.

The evolution of the chemical and electronic state was also monitored during ILG and FcRG with in situ X-ray absorption near-edge structure (XANES) measurements. The normalized W L₃-edge XANES spectra measured at different voltages are shown in FIG. 5C. All the W L₃-edge XANES spectra exhibit a broad white-line feature, and the line-shape of all the curves are similar. To distinguish subtle changes to the W oxidation state, differential curves were plotted between the gated spectra and the pristine spectrum, as shown in FIG. 5D. If the sign of the differential peak is positive near the white-line at 10.206 KeV, the W cation is reduced, leading to partial filling of the W 5d⁰ orbital. As for conventional ILG, there is negligible electron injection at 1.0 V since no peak appears in the differential curve. Above 2.0 V, a pronounced peak appears and its signal increases with voltage up to 4.0 V. Notably, the differential peak is composed of both a shift in the W L₃-edge and a larger white-line peak, which strongly suggests W is reduced during the ILG process. Another feature appears at a higher energy position (10.26 KeV), implying a pronounced change in the local coordination of the W cation at higher ILG voltages. Together with the XRD results in FIG. 5A and transport behavior in FIG. 4A, it can be concluded that the conventional ILG process involves a structural phase transition and chemical modification as driven by ionic defect formation or ionic intercalation. The whole WO₃ film seems mostly disordered or amorphized after reaching 4.0 V as evidenced by the fully suppressed (002) film Bragg peak.

In comparison, the FcRG leads to much gentler evolution, especially with regard to the chemical and electronic state. FIGS. 4A and 5A show that while the resistance drops a hundred-fold as the gate voltage is changed from 1.0 V to 1.4 V, little to no change is observed in the atomic structure. Meanwhile, a barely resolved broad hump near the white-line peak can be seen in the differential XANES curve (FIG. 5D) for voltages at 1.4 V or less; this can again be attributed to electron injection into the 5d-O 2p states of W by the redox gating doping process. The obvious rising edge shift and secondary peak located at 10.26 KeV for the case of ILG is entirely absent for the FcRG process, which suggests almost no chemical modification or changes in local coordination for gate voltages below 1.4 V. As the voltage exceeds 1.4 V, FcRG is no longer a pure carrier injection process and becomes gradually dominated by ionic processes due to the inevitable electrochemical reactions.

### Example 2

In this example, redox gating in accordance with embodiments of the disclosure was achieved using FcRG in a LNO thin film transistor. FcRG were prepared as in example 1. Epitaxial c-axis oriented LNO films (40 unit cells) grown on the (LaAlO₃)_{0.3}(Sr₂TaAlO₆)_{0.7} (LAST) substrate by ozone-molecular beam epitaxy, and its lattice constant is 3.868 Å were used in this example. The lattice constant of the LNO thin film is 3.83 Å, therefore, the film fully strains on the substrate due to small lattice mismatch between the two materials. More details on the chemical structures are provided in the following section of Materials and Methods.

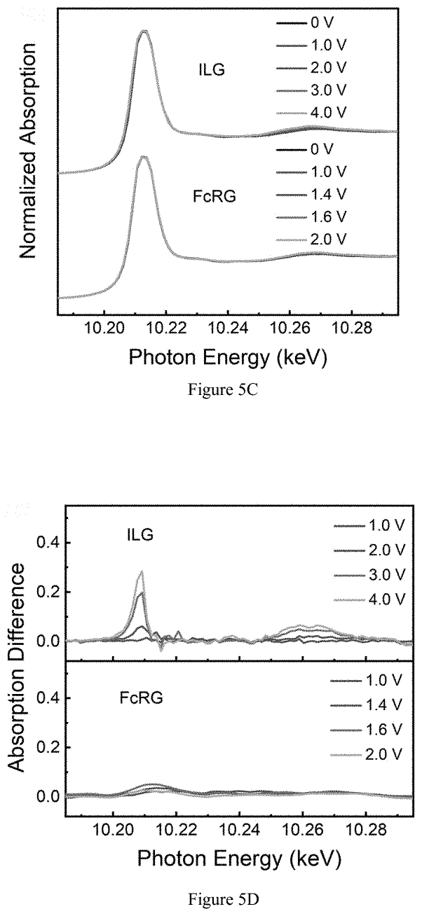

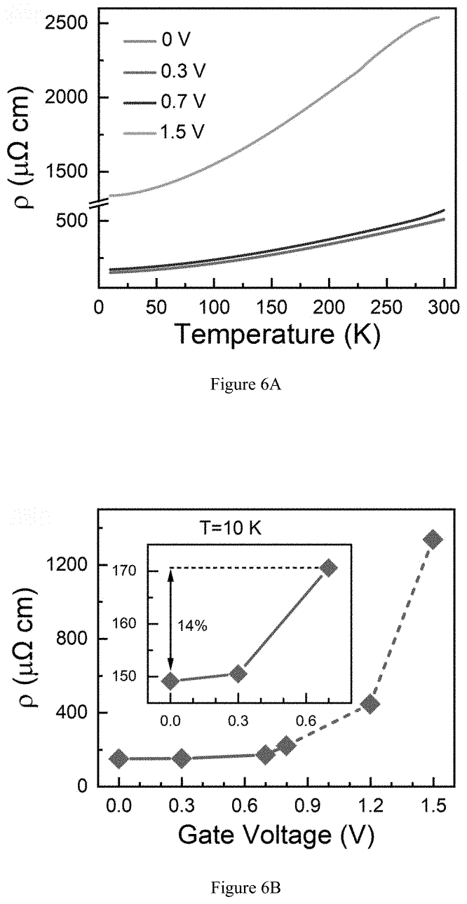

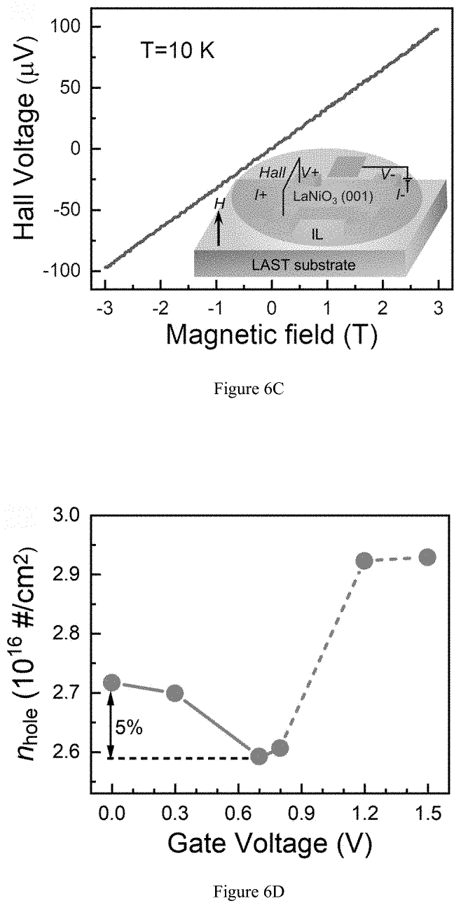

Given that the FcRG-gated LNO film at the gate voltages of 0-1.5 V remains metallic in the measured temperature range and electron injection would increase the sheet resistivity of LNO film, metallic LNO was selected to evaluate the redox gating-induced carrier density in accordance with the disclosure. Referring to FIG. 6A, the temperature dependence of LNO sheet resistivity was measured when gated by FcRG in accordance with the disclosure at different gate voltages. A significant increase in resistivity is observed as the gate voltage increases. Referring to FIG. 6B, the gate voltage-dependent resistivity of FcRG-gated LNO film at 10 K revealed that 0.7 V was a critical point of the gate voltage, at which the resistivity increased by 14%. At V_{G}<0.7 V, the resistivity increased slowly, whereas at V_{G}≤>0.7 V, the resistivity changed sharply. At V_{G}=1.5 V, the resistivity increase is about 800%. Referring to FIG. 6C, Hall measurement was performed by applying an ac current of 10 μA through the channel and the positive Hall slope confirmed that LNO is p-type conduction. Referring to FIG. 6D, 1.8×10¹⁴-1.3×10¹⁵ cm² carrier densities are induced in LNO at the gate voltage of 0.3-0.7 V and the charge carrier density is reduced by 5% at V_{G}=0.7 V. Such giant carrier densities induced by redox gating at the low gate voltage are comparable to those obtained at high gate voltages in ever-reported ionic gating systems. Under the redox gating, electrons are injected into the LNO film and combined with the conductive charge carriers (holes), leading to an increase in the sheet resistivity. Therefore, the carrier injection in the process of redox gating contributes to the control and modulation of charge transport and phase transformation in the redox-gated thin film transistors.

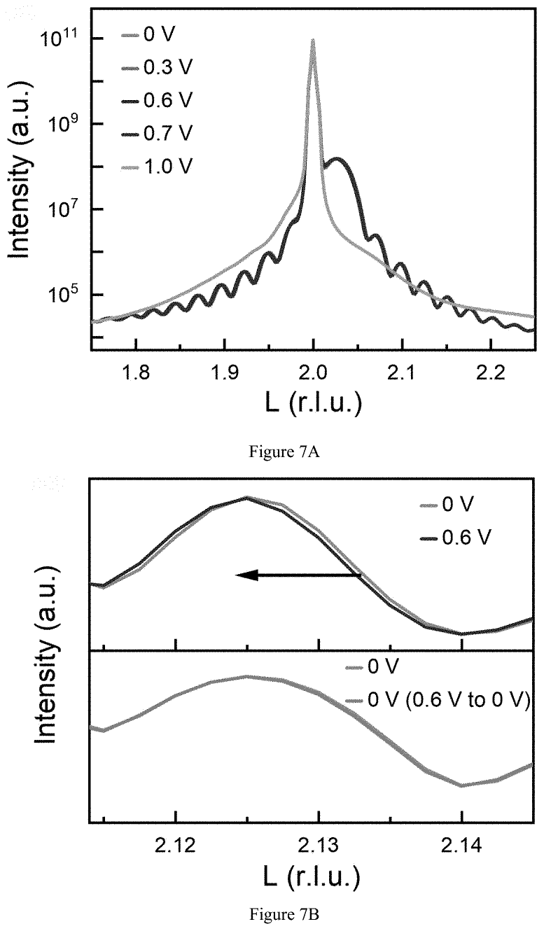

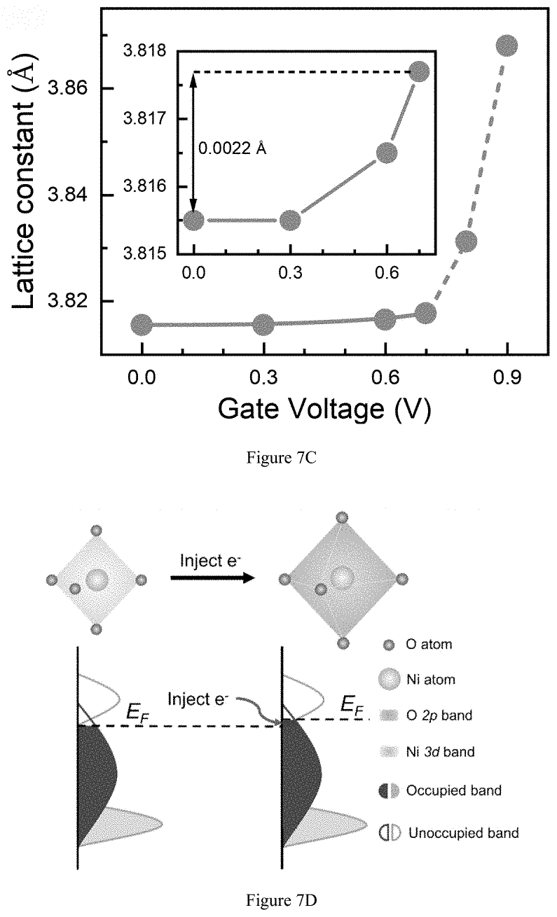

in situ XRD were performed to reveal the variation of lattice structure during redox gating process from 0 V to 1.0 V. Referring to FIG. 7A, the clear thickness oscillation fringes around the LNO (002) peaks prove that the LNO films were of high quality at V_{G}≤0.7 V, while the thickness oscillation fringes disappeared at V_{G}=1.0 V, indicative of the degradation of LNO film. Referring to FIG. 7B, FcRG-gated LNO film shows a lattice expansion at V_{G}=0.6 V and such a lattice expansion is revisable. FIG. 7C summarizes the relationship of lattice constant and gate voltages. The lattice constant varied with the gate voltage, exhibiting a similar behavior to the changes of LNO sheet resistivity. The lattice constant slowly increased by 0.0022 Å at V_{G}=0.7 V, in agreement with Sawatzky theoretical study. FIG. 7D schematically depicts the changes in Ni—O octahedron and band structure after electron injection. When electrons are injected into the LNO film, they combine with the ligand holes and shift the Fermi level, thereby leading to Ni—O octahedron expansion and the increase of lattice constant. When the gate voltage is greater than 0.7 V, the lattice constant increases sharply due to the formation of oxygen vacancies. Such lattice structure changes arising from redox gating is reversible at low gate voltages (V_{G}≤0.7 V), while the changes caused by the formation of oxygen vacancies is irreversible at high gate voltage (V_{G}>0.7 V).

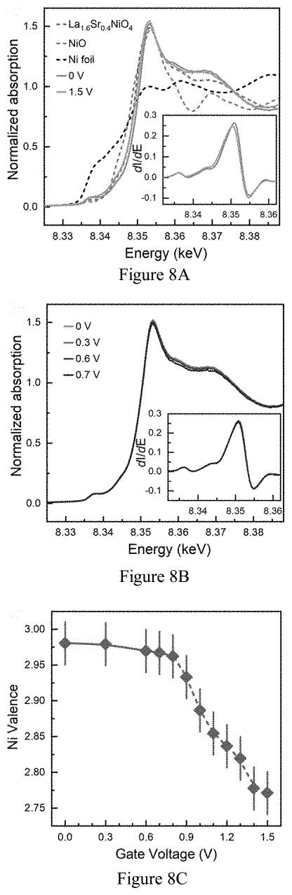

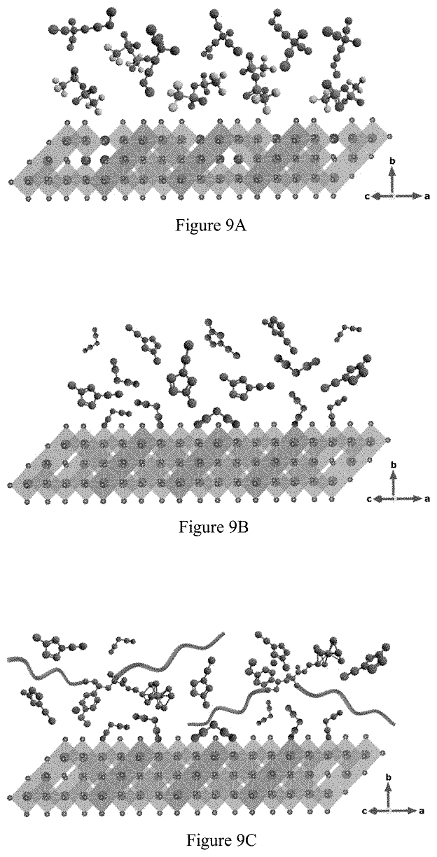

Referring to FIG. 8, the in situ Ni K-edge XANES spectra of FcRG-gated LNO film at different gate voltages give evidence on the origination of lattice expansion and resistivity variation. The absorption edge shifted ˜0.55 eV to a lower energy at V_{G}=1.5 V (FIG. 8A), in comparison with that at V_{G}=0 V. Such a shift is more pronounced for the first derivative Ni K-edge XANES spectra (dI/dE, I is the intensity and E is the energy) from V_{G}=0 V to V_{G}=1.5 V. The peak moves to the lower energy. FIG. 8B compares those XANES spectra at low gate voltages and demonstrate that the K-edge position has no obvious shift at V_{G}≤0.7 V. By assuming a linear relation between the valence of Ni and the peak position of d/dE, the valence of Ni at different gate voltages can be derived (FIG. 8C). The valence of Ni decreases 0.6% at V_{G}<0.8 V, while the valence of Ni rapidly decreases to 2.77 at V_{G}=0.8 V. For V_{G}<0.8 V, electrons provided by FcRG gating media are injected into the LNO film, and further combine with holes in the films, leading to the decrease in the charge carrier density and the increase in the LNO sheet resistivity.

### Example 3

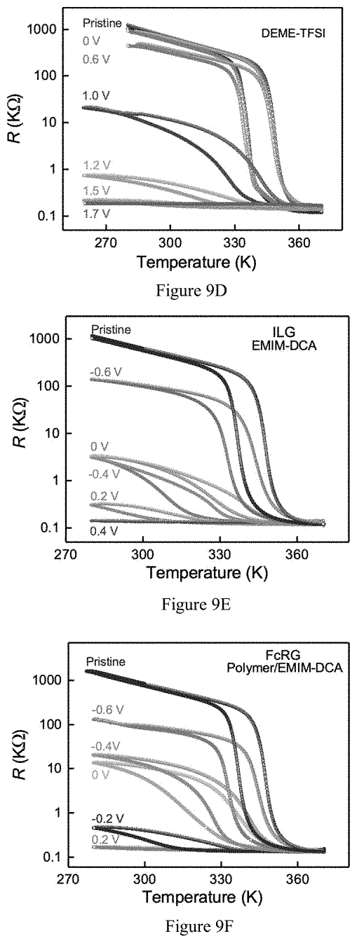

In this example, redox gating in accordance with embodiments of the disclosure was achieved using ILG and FcRG in a VO₂ thin film transistor. ILG and FcRG were prepared as in example 1. DCA anions in ILG can coordinate to V atoms on the surface of VO₂ film, leading to a reversible conversion between V⁴⁺ and V³⁺ with a redox potential of ˜0.3-0.4 V (FIG. 9B). So, ILG itself can function as the redox gating materials in the case of VO₂ thin film transistor. It should be emphasized that FcRG has a pair of redox reactions: V⁴⁺+e=V³⁺ and Fc⁺+e=Fc (Fc=ferrocene) with a redox potential difference of ˜0.2 V (FIG. 9C). For comparison, DEME-TFSI was used as a control for conventional ionic gating (FIG. 9A). DEME-TFSI ILs has been widely used in the past for the ionic gating of VO₂. VO₂, an archetypal correlated material with a half-filled outer shell electronic state, possesses an intriguing MIT with a concomitant change in lattice structure from a rutile to a monoclinic type. VO₂ films were grown on Al₂O₃ (0001) single crystal substrates by radio frequency (rf) plasma-assisted oxide molecular beam epitaxy. The thickness of the film was about 30 nm. Standard photolithography together with liquid-nitrogen cooled Ar-ion milling was used to pattern Hall bar devices. The gate voltage was applied using a platinum pads deposited on the side of the channel. The transport measurement was performed in a cryostat with a vacuum environment of about 10 mTorr. More details on the chemical structures are provided in the following section of Materials and Methods.

DEME-TFSI, ILG and FcRG were applied to investigate gate control of the MIT in VO₂ film and a pronounced difference is observed in the critical gate voltage required to suppress the insulating phase as the temperature is lowered. In these measurements, the pristine sample with no gating materials covering the VO₂ surface was used to start. A first order and hysteretic MIT is observed in the pristine sample at temperature of around 340 K, close to the observation in bulk single crystal VO₂ samples. The gating materials were then transferred onto the device covering both the VO₂ channel and the side-gate Pt pad. Referring to FIG. 9A, the resistance of DEME-TFSI-gated VO₂ film in the insulating state decrease as the gate voltage gradually increases. The MIT is suppressed at V_{G}≤>1.5 V, comparable to those previously reported in literatures. Referring to FIG. 9B, the resistance of ILG-gated VO₂ film has dropped by more than two orders of magnitude at the zero gate voltage when the temperature is lowed from 370 K. As a positive gate voltage is applied, the resistance of VO₂ film continues to decrease and a metallic state is obtained with a gate voltage of 0.4 V. Applying a negative gate voltage of −0.6 V can restore the insulating state resistance to within one order of magnitude of that of the pristine sample. Referring to FIG. 9C, an even lower critical gating voltage of about 0.2 V is observed in FcRG-gated VO₂ film upon reversible control of the MIT of VO₂.

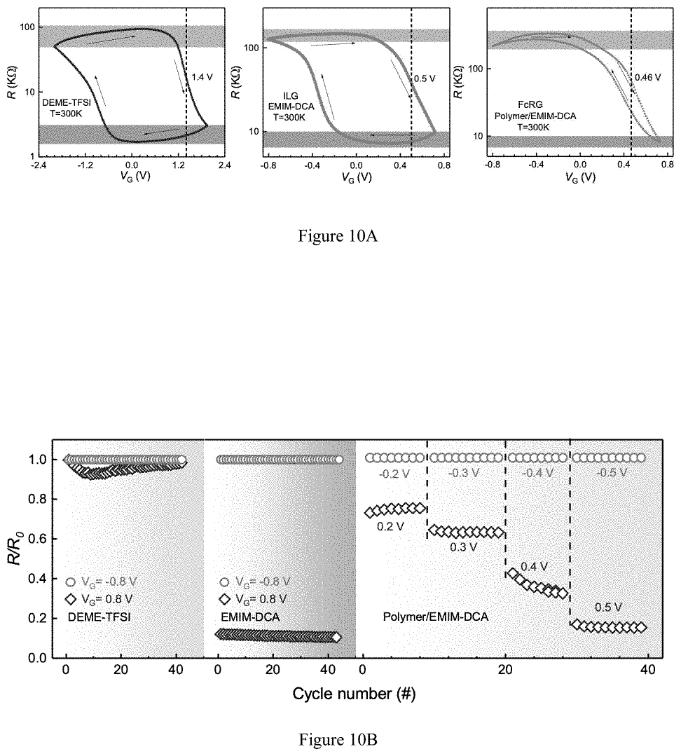

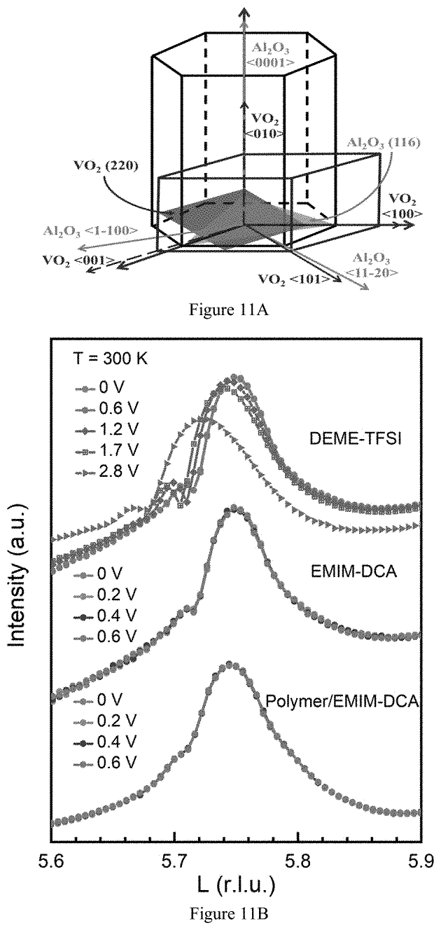

The gate voltage dependence of the resistance of VO₂ was measured at a fixed temperature of 300 K by sweeping the gate voltages from positive to negative and back to positive continuously. Referring to FIG. 10A, a significant difference in critical gate voltages was observed among three different electrolytes. ILG and FcRG redox gating require much lower gate voltages than DEME-TFSI ionic gating in achieving over one order of magnitude reduction in VO₂ resistance. Besides, ILG gating with one redox reaction produced a non-volatile behavior, that is, the low-resistance state was maintained when the positive gate voltage was reduced to 0 V, while FcRG gating with a redox reaction pair produced a much stronger dependence of resistance on the gate voltages. These observations suggested that the redox reactions of polymers in the redox gating materials in accordance with the disclosure played key role in the gating process.

The cycling capability of the modulation of the resistance was further investigated by switching the gate voltages between positive and negative values back and forth in a successive manner. The maximum amplitude of the V_{G} used in this measurement was 0.8 V. Referring to FIG. 10B, the conventional DEME-TFSI ionic gating shows no tunability on VO₂ sheet resistance, while ILG redox gating achieves a steady control of the resistance by about one order of magnitude with the same amplitude of gate voltage. FcRG redox gating was performed by increasing the magnitude of gate voltages gradually and a stable control of resistance was achieved at the gate voltage of 0.2-0.5 V. It is evident that redox gating requires a sub-volt gate voltage to control the MIT in VO₂

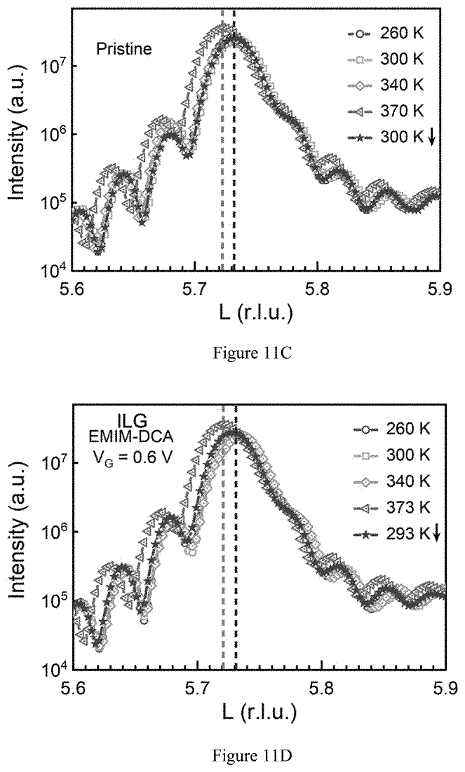

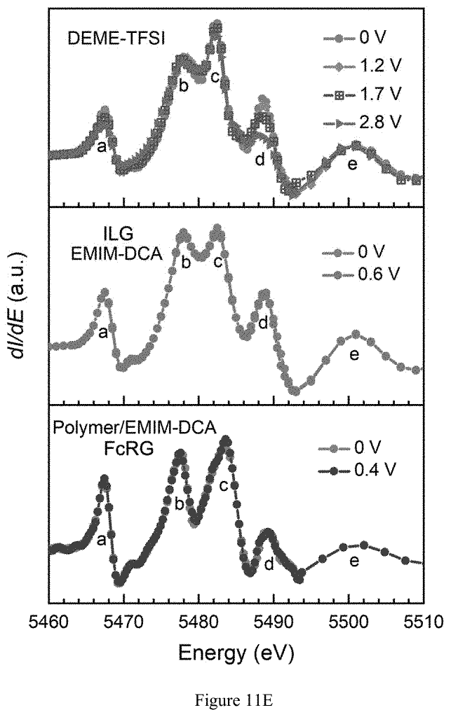

in situ XRD and XANES measurements were performed to probe the effect of redox gating on the lattice structure and chemistry of VO₂ films. FIG. 11A is a schematic illustration of the epitaxial relationship between VO₂ thin film and Al₂O₃ substrate and FIG. 11B is the specular reflection of VO₂ films under different gate voltages at room temperature. At V_{G}=0.6 V using ILG and FcRG, there was no observed change in the Bragg peak position, indicating that the structure of VO₂ film remained in the monoclinic phase in the metallic phase.

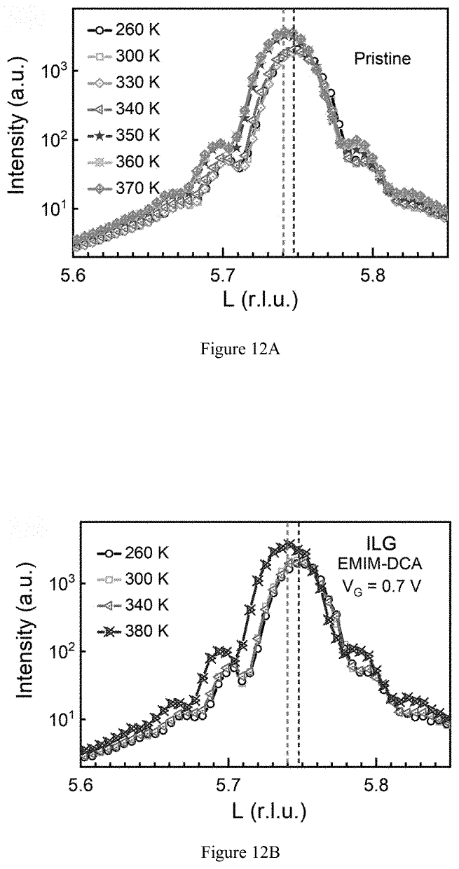

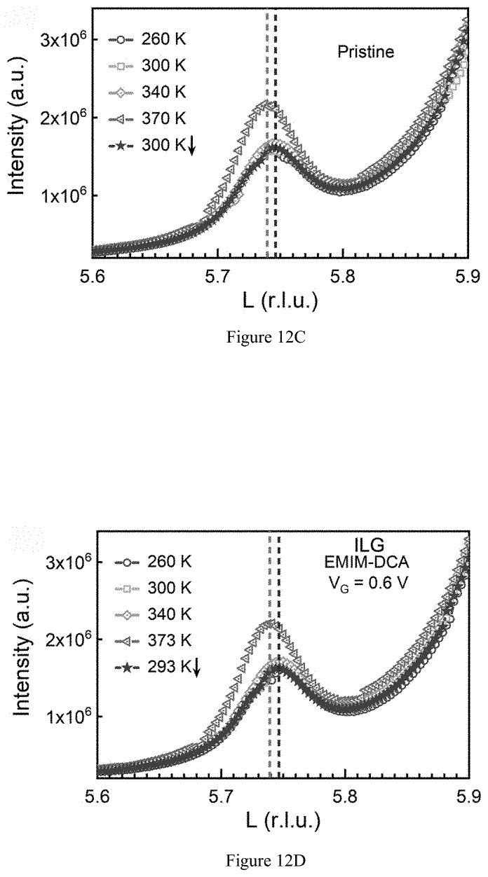

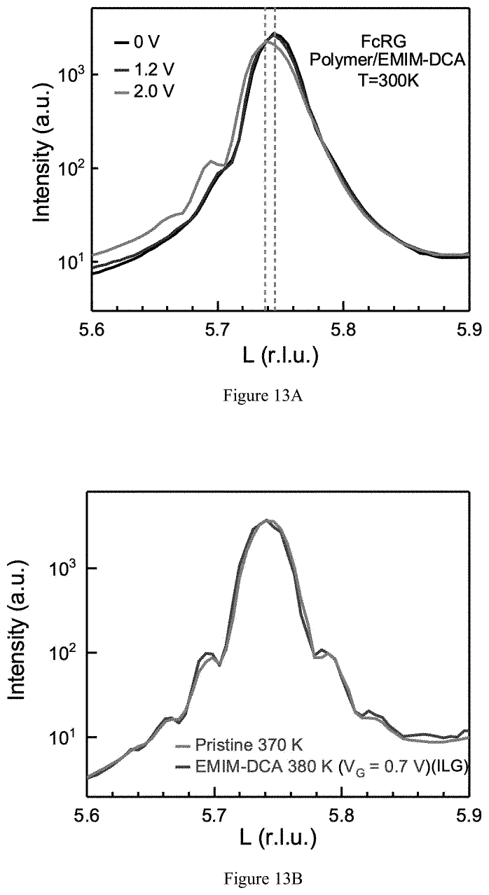

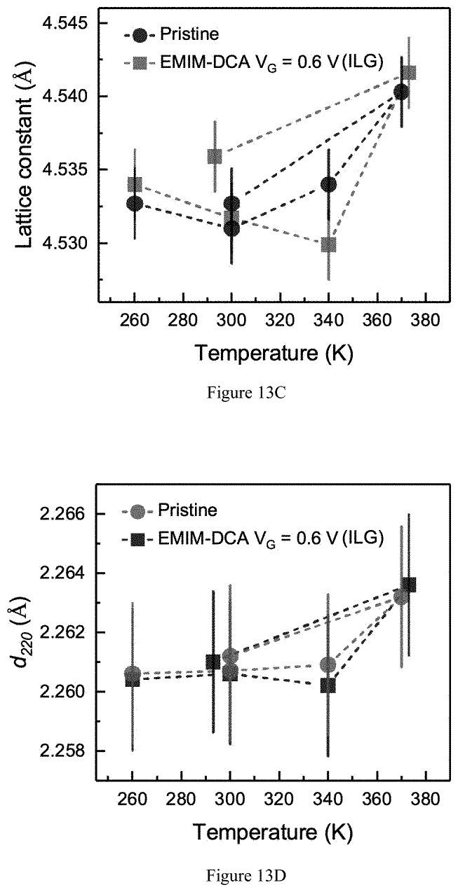

Referring to FIGS. 11C and 11D, in situ XRD measurement at different temperatures revealed the temperature-driven structural transitions in VO₂ film. Referring to FIG. 11C, the pristine VO₂ film at low temperature (T<340 K) is in the monoclinic phase, while at the temperature above 340 K, the lattice structure of VO₂ film transforms into the tetragonal phase. Such a temperature-driven structural transition is reversible. When the temperature decreases to 300 K, the structure changes from tetragonal phase back to monoclinic phase. Adding ILG on pristine thin film and applying gate voltage (V_{G}=0.6 V) (FIG. 11D), the temperature-dependence of VO₂ lattice structure varied with the same as the pristine film (FIG. 11C). Referring to FIGS. 12C and 12D, the variation of VO₂ (220) peak with temperature in pristine and gated VO₂ film further verified the above mentioned observations. FIGS. 13C and 13D summarizes the lattice constant and (220) spacing of VO₂ films. It is evident that redox gating is capable of decoupling the electrical transformations between metallic and insulating phases with the structural transitions between monoclinic and tetragonal phases.

Referring to FIG. 11E, the first derivative V K-edge XANES spectra showed no changes of the local structure and valence of V⁴⁺ ions in the range of gate voltages up to 0.8 V. The various absorption features are identified and labelled as a-e. The pre-edge feature a represents the dipole-forbidden transition 1 s→3d and its intensity and position depends on the local coordination environment and oxidation state, because the hybridization of V 3d orbitals and O 2p states leads to the p component of the dipole transition to the hybridized states. The main absorption edge b stood for the excitation of a core photoelectron into the continuum. The near-edge features c-e above the absorption edge were not only multiple scattering but also caused by the dipole-allowed excitation of a core 1 s electron of V to a localized 4p state. The top panel in FIG. 11E is the first-order derivative of the V K-edge XANES under the ionic gating of DEME-TFSI. As the gate voltage increases, the position of feature a shifted to the low energy direction, and the peak intensity gradually decreased. These results reveal that the vertical asymmetry of the apical V—O bond became more symmetric for V_{G}=1.7 V and 2.8 V, indicating a decrease in the valence of V and a structural change of oxygen around vanadium. In addition, the intensity difference among features c, d and e for different gate voltages confirmed the lower electronic empty density of state around the V sites in VO₂ at high gate voltages. In contrast to DEME-TFSI, these features of V K-edge XANES spectra of ILG and FcRG-gated VO₂ films had exceedingly small changes, giving evidence on no change in the local structure and valence of vanadium.

Taken together, redox gating could significantly reduce the critical gate voltage by nearly eight times into a sub-volt regime in a VO₂ thin film transistor, thereby leading to the improvement of cyclability. This further confirmed the unique capability of redox gating. Besides, it is crucial that the VO₂ films maintain a monoclinic structure in the process of redox gating when the sheet resistance decreases more than four orders of magnitude. This has demonstrated that redox gating is a simply and practical way to reversibly control the MIT of VO₂ in a single monoclinic phase. Technologically, these developments on stabilizing the monoclinic metallic phase makes the application of VO₂ in advanced electronic devices more readily relevant. A MIT without a structural transition can provide a significantly improved device longevity and operation response time.

### Materials and Methods

### Materials:

EMIM-DCA (≥98.0% (metals basis)); DEME-TFSI (for electrochemistry, ≥98.5% (qNMR))); Cu(I)Br (99.99%); ferrocenylmethyl methacrylate (95% (NMR), contains Ionol® 46 (Raschig GmbH) as inhibitor,); 4-vinylpyridine (95%, contains 100 ppm hydroquinone as inhibitor); 1,4-dioxane (≥99%); bromoethane (≥98%); N,N-dimethylformamide (DMF, ≥99%); chloroform (≥99%); methanol (≥99.8%); acetonitrile (≥99.5%); diethyl ether (Et₂O, ≥98%, contains ≤2% ethanol and ≤10 ppm BHT as inhibitor); 3-bromothiophene (97%); 2,2′-azobis(2-methylpropionitrile) (AIBN, recrystallized from methanol, 99%); [1,3-bis(diphenylphosphino)propane]dichloronickel(II) (Ni(dppp)Cl₂); n-butyllithium (nBuLi) solution (2.5 M in hexanes); isopropylmagnesium chloride lithium chloride complex solution (i-PrMgCl.LiCl, 1.3 M in THF); 1,6-dibromohexane (96%); N-bromosuccinimide (NBS, 99%); 1-methylimidazole (99%, purified by redistillation). Unless stated otherwise, all reagents and chemicals were obtained from Sigma-Aldrich and used as received without further purification. Tetrahydrofuran (THF) and hexane were dried using an MBraun MB-SPS 800 solvent purification system.

### PIL Synthesis:

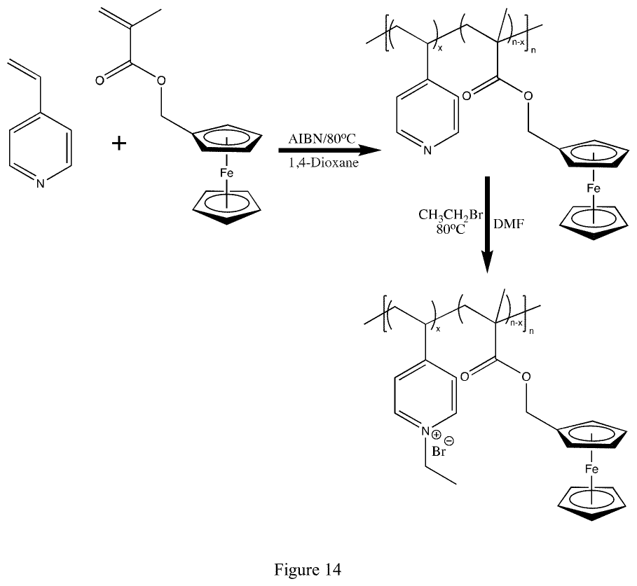

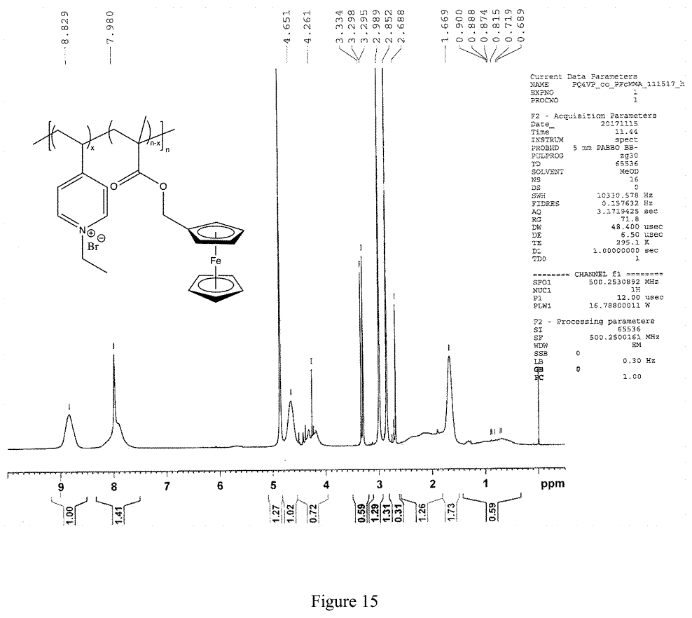

Poly(1-ethyl-4-vinyl pyridine-1-ium bromide)-co-poly(ferrocenylmethyl methacrylate) (PQ4VP-co-PFcMMA): The synthetic procedures are provided in FIG. 14. Polymerizations of ferrocenylmethyl methacrylate and 4-vinylpyridine were conducted in degassed 1,4-dioxane solutions. Weighted amounts of monomers, AIBN initiator, and 1,4-dioxane in Fisher-Porter tubes, equipped with a valve, and degassed at 20-30 mTorr by three alternate freeze-thaw cycles. After degassing, the tubes were placed in an 80° C. constant-temperature bath controlled to ±0.1° C. Upon completion of polymerization, the polymer was precipitated from 1,4-dioxane by dropwise addition to excess water. The polymer was filtered and redissolved in 1,4-dioxane and reprecipitated two more times, and then residual solvent was removed under vacuum. The quaternization of pyridine functional groups in the polymer was performed in DMF solutions and refluxed with bromoethane at 80° C. The final polymer was precipitated by diethyl ether and then residual solvent was removed under vacuum. The ¹H NMR spectrum of PQ4VP-co-PFcMMA copolymer is provided in FIG. 15. The mole ratio of PQ4VP and PFcMMA is 2:1.

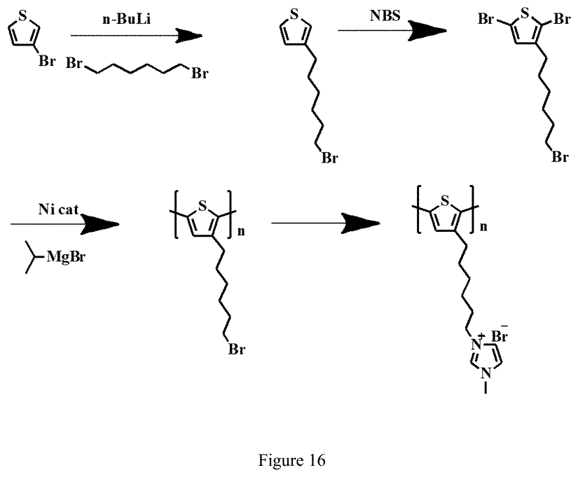

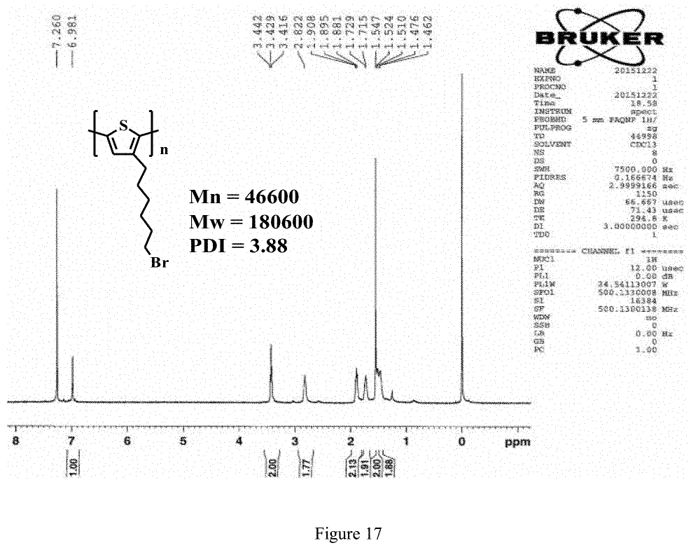

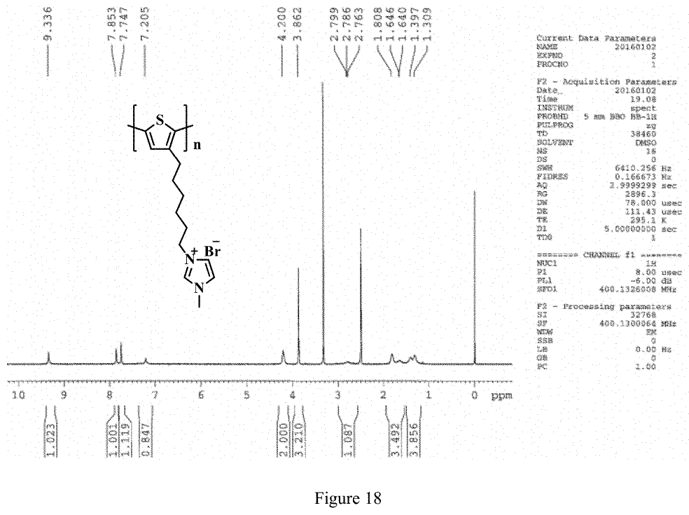

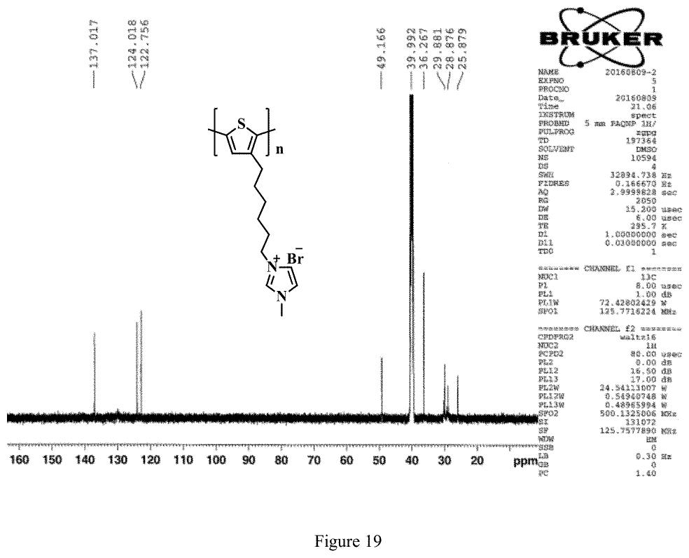

Poly(3-[6-(2,5-dimethylthiophen-3-yl)hexyl]-1-methyl-1H-imidazol-3-ium bromide)(PTImBr): Imidazolium-substituted polythiophenes were prepared according to a recently reported method. The synthetic procedures are provided in FIG. 16. 5 g of 3-bromothiophene was dissolved in 60 mL of dry, degassed hexane in a dry Schlenk flask under argon and the solution was cooled down to −78° C. in the liquid N₂/isopropanol cold bath. 12.2 mL of nBuLi solution (2.5 M in hexanes) was added dropwise and the mixture was stirred for 30 min and then 5 mL of dry THF was added slowly via syringe. The reaction was kept at −78° C. for 1 hour and then warmed up to 0° C. 20 mL of 1,6-dibromohexane with other THF (3 mL) was added and the solution could warm to room temperature. After stirring at room temperature for 12 hours, the mixture was extracted diethyl ether and then dried by Na₂SO₄. The residue was purified by column chromatography (silica, hexane, TLC: R_{f}=0.65) and vacuum distillation to remove to remove traces of 1,6-dibromohexane to afford 3.45 g of 3-(6-bromohexyl)thiophene as a colorless oil. 3.45 g of 3-(6-bromohexyl)thiophene was further brominated with 5.22 g of NBS in 50 mL of chloroform in dark for 12 hours and 4.64 g of 2-bromo-3-(6-bromohexyl)thiophene was obtained as a colorless oil after column chromatography (silica, hexane, TLC: R_{f}=0.60). Polymerization of 2-bromo-3-(6-bromohexyl)-5-iodothiophene was carried out using Ni(dppe)Cl₂ as the catalyst. 3.35 g of 2-bromo-3-(6-bromohexyl)-5-iodothiophene was added to a dry two-neck flask and dissolved in 100 mL of dry THF. The reaction mixture was pumped and filled with dry N₂, and then cooled to 0° C. 6.19 mL of i-PrMgCl.LiCl solution was added dropwise and the mixture was stirred at 0° C. under inert atmosphere for 30 min. To start the polymerization, 33.54 mg of Ni(dppp)Cl₂ catalyst was added and the mixture was stirred for 2 h at 40° C. and 12 h at room temperature. The polymer was precipitated into an ice-cold HCl/MeOH (5%) mixture filtered off on a PTFE membrane (47 mm/0.45 μm). The polymer was purified using Soxhlet extraction for 24 h with methanol, hexane, and chloroform, respectively. After evaporation of the solvent, the residue was redissolved in chloroform and precipitated again from methanol, filtered, washed with methanol, and dried, affording 1.82 g of poly[3-(6-bromohexyl)thiophene] (P3BHT) precursor polymers as a black-red powder. For polymer functionalization with 1-methylimidazole, 200 mg of P3BHT precursor polymers were suspended in 50 mL of acetonitrile and then refluxed in dry N₂ for 36 hours. After cooling down, the reaction mixture was added dropwise to Et₂O and a dark precipitate was obtained. The precipitated polymer was filtered off using a PTFE membrane (47 mm/0.45 μm) and (freeze-)dried carefully, affording PTImBr polymers as a purple-black powder. The characterization data are provided in FIG. 17-19.

### Redox Gating Materials:

In contrast to conventional ionic gating materials using pure ionic liquids (ILs), redox gating materials used in three examples are made of the EMIM-DCA IL solutions of redox-active imidazole-functionalized conjugated polythiophene PIL (PTImBr), ferrocene-containing PIL (PQ4VP-co-PFMMA), or copper(I) salts (copper(I) bromide, CuBr). 10 wt % of PQ4VP-co-PFMMA polymers, 4 wt % of PTImBr polymers, and 300 mM CuBr salts were dissolved in EMIM-DCA ILs and stirred for 24 hours in a nitrogen glovebox until the solutions were clarified. They are appointed as FcRG, PTRG, and CuRG, respectively, while the pure conventional EMIM-DCA IL is named as ILG, as shown in FIG. 3.

Growth of WO₃, LNO, and VO₂ Thin Films:

WO₃ thin films were grown on 10 mm×10 mm LaAlO₃ (001) single crystal substrates by RF sputtering system with a WO₃ ceramic target. To obtain WO₃ films with high sheet resistance (e.g., stoichiometric insulating phase), the deposition temperature was set at 750° C. and the gas pressure was kept at 50 mTorr with Ar/O₂ ratio of 1:2 (Ar 24 sccm and O₂ 48 sccm). After deposition for 1 h, the films were further annealed at 650° C. with pure O₂ oxygen atmosphere of 48 sccm for 3 h.

The LaNiO₃ film was grown on (LaAlO₃)_{0.3}(Sr₂AlTaO₆)_{0.7} (LSAT) substrates using ozone-assisted molecular beam epitaxy. To ensure a good stoichiometry of La and Ni elements, the growth parameter were controlled using Rutherford backscattering spectrometry combined with low angle X-ray reflectivity measurement.

High-quality single crystal VO₂ thin film was epitaxially grown on a two-inch size Al₂O₃ (0001) single crystal wafer. By controlling the vanadium-oxygen beam flux, a high quality VO₂ thin film with perfect V—O stoichiometry can be obtained.

### Field Effect Device Fabrication:

Pt electrodes were deposited by sputtering system with the help of mask to fabricate FET devices with a channel length of 0.5 mm. At the same time, an area with 1 mm×1 mm Pt electrode was deposited as the bottom electrode to increase the contact area during gating process, which served as bottom electrodes. A Pt wire was used as top electrode. To avoid the contact between the gating materials and the Pt electrodes during the gating process, Al₂O₃ insulator layer was deposited by sputtering on the top with the source and drain electrodes exposed.

### Electrical Characterization:

The I-V tests for all four types of gating materials were performed on WO₃ FET devices in glove box with N₂ atmosphere and the gating voltage was supplied by a Keithley 2400 digital source meter. The carrier density could be estimated by the equation:

$${n}_{2 D} = \frac{Q}{e A} = \frac{\int {I}_{G} d {V}_{G}}{e A d {V}_{G} / d t}$$

where I_{G} is the gating current, dV_{g}/dt is the gating voltage speed that is a fixed speed of 1 mV/s, and A is the area of the channel. Thus, integrating the I-V curves with the applied gating voltages gives the gating-induced carrier densities.

### Hall Measurement:

The LNO sample used in the Hall measurement has 40-unit cells with a thickness of about 15.3 nm. The Hall bar devices were fabricated from LNO films using standard photolithography. The area of the Hall bar was defined by Ar-ion milling, during which liquid-nitrogen was used to cool the sample to prevent the formation of oxygen vacancies in LNO. Electrical contacts were made by depositing 50-nm thick platinum on the device using dc sputtering. The channel of the Hall bar has a dimension of 0.5×1.0 mm². A platinum wire was used as the positive electrode, which is suspended above the channel area and is in contact with the electrolyte. The negative gating electrode shares the same Pt contact connected to the negative lead of the current source. The Hall measurement was performed using a Quantum Design PPMS system. The gating voltage was applied at 300 K with a vacuum environment of about 10 torr. An ac electric current of 10 μA was applied through the LNO channel. To reduce electric conduction through the electrolytes, the Hall measurement was conducted at 10 K, where the electrolytes is completely frozen. The magnetic field is applied up to 3 Tesla.

### In Situ X-Ray Diffraction (XRD):

The in situ XRD experiments were performed at the beamline 12-ID-D at Advanced Photon Source (APS), Argonne National Laboratory (ANL). The X-ray energy is 20 keV with beam size of 0.5 mm×1.5 mm and flux ˜1×10¹² photons/sec. In XRD measurements, an 8 μm thick Kapton foil was used to cover the gating materials to guarantee the liquid electrolyte is thin enough. To ensure the same condition as the transport test, a shield made by Kapton foil was applied to cover the cell and N₂ was flowed during the entire in situ XRD process.

### In Situ X-Ray Absorption Spectroscopy (XAS):

The in situ XAS were conducted at the beamline 12-BM at APS, ANL. The setup of gating device is the same as that in the in situ scattering experiment. All measurements were carried out at room temperature with the beamline energy resolution set to ˜0.5 eV. The sample surface was at grazing incidence angle (<5°) and the detector at 90° emission angle relative to the incident x-ray beam was used to record the XANES spectra in the total fluorescence yield (TFY) mode. The XANES data normalization were processed by Athena software.

What is claimed:

1. A redox gating material, comprising:
an admixture of
(a) one or more redox agents, the one or more redox agents comprising transition metal salts with variable valency and/or at least one redox-active functional group; and
(b) one or more of ionic electrolytes,
wherein the one or more redox agents have standard redox potentials of about −1 V to about 1V;

2. The redox gating material of claim 1, wherein the redox gating material is in a liquid or a gel state.

3. The redox gating material of claim 1, wherein the redox gating material is electron-injecting or hole-injecting.

4. The redox gating material of any one of the preceding claims, wherein the one or more redox agent comprise one or more of the transition metal salts with variable valency.

5. The redox gating material of claim 4, wherein the one or more transition metal salts with variable valency comprises one or more of Cu ions, Fe ions, V ions, Co ions, Ni ions, and their corresponding coordination ions.

6. The redox gating material of any one of the preceding claims, wherein the one or more redox agents comprise one or more redox-active functional groups.

7. The redox gating material of claim 6, wherein the one or more redox-active functional group is selected from the group consisting of ferrocene, viologen, quinone, TEMPO, thiophene, benzophenone, ferrocyanide, ferricyanide, and combinations thereof.

8. The redox gating material of claim 6 or 7, wherein the redox agent comprises one or more of poly(ionic liquids) comprising the one or more redox-active functional groups and ionic liquid species in monomer repeating units, connected through a polymeric backbone to form a macromolecular architecture.

9. The redox gating material of claim 8, wherein the ionic liquid species comprises one or more of quaternary imidazolines, quaternary pyridines, ferrocenium, cobaltocenium, ferrocyanide, ferrocyanide, dicyanamide, bis(trifluoromethylsulfonyl)imide, and hexafluorophosphate.

10. The redox gating material of claim 8 or 9, wherein the one or more poly(ionic liquid) comprises one or both of a conjugated poly(ionic liquid) and a metal-containing poly(ionic liquid).

11. The redox gating material of claim 10, wherein the conjugated poly(ionic liquid) comprises one or more of polythiophene poly(ionic liquid), poly(quinone) poly(ionic liquid), and poly(viologen) poly(ionic liquid).

12. The redox gating material of claim 11, wherein the polythiophene poly(ionic liquid) comprises one or both of 3,4-ethylenedioxythiophene and imidazole-functionalized thiophene monomers.

13. The redox gating material of claim 11, wherein the poly(quinone) poly(ionic liquid) comprises repeating quinone isomers.

14. The redox gating material of claim 13, wherein the repeating quinone isomers comprises one or more of benzoquinones, naphthoquinones, anthraquinone, and phenanthraquinones.

15. The redox gating material of claim 11, wherein the poly(viologen) poly(ionic liquid) comprises one or both of conjugated bi-/multi-pyridyl groups and 1,1′-disubstituted-4,4′-bipyridiliums.

16. The redox gating material of claim 8, wherein the metal-containing poly(ionic liquid) comprises one or more of ferrocene-containing poly(ionic liquids), ferrocyanide-containing poly(ionic liquids), and ferricyanide-containing poly(ionic liquids).

17. The redox gating material of claim 13, wherein ferrocene-containing poly(ionic liquids) comprises one or more of ferrocenylenes, ferrocenylsilanes, and pendant ferrocenes.

18. The redox gating material of any one of the preceding claims, wherein the transition metal salt is present in an amount below the saturated concentration in electrolyte solutions

19. The redox gating material of any one of claims 8 to 17, wherein the redox gating material is a liquid solution, and the poly(ionic liquid) is present in the redox gating material in an amount of about 1 wt % to about 15 wt % based on the total weight of the redox gating material.

20. The redox gating material of any one of claims 8 to 17, wherein the redox gating materials is an ionogel and the poly(ionic liquid) is a redox-active polymer present in an amount of at least about 15 wt % based on the total weight of the redox gating material.

21. The redox gating material of any one of the preceding claims, wherein the redox agent comprises a redox-active functional group, and the one or more redox-active functional groups are present in an amount of at least about 5% by mole of the redox-active functional groups based on the total mole of the redox gating material.

22. The redox gating material of any one of the preceding claims, wherein the ionic electrolyte is one or more of ionic liquids.

23. The redox gating material of claim 22, wherein the ionic liquid comprises one or more of:
1-ethyl-3-methylimidazolium dicyanamide (EMIM-DCA),
1-Butyl-3-methylimidazolium dicyanamide (BMIM-DCA),
1-ethyl-3-methylimidazolium bis(trifluoromethylsulfonyl)imide (EMIM-TFSI), and
diethylmethyl(2-methoxyethyl)ammonium bis(trifluoromethylsulfonyl)imide (DEME-TFSI).

24. A gated channel comprising:
a channel material and the redox gating material of any one of the preceding claims.

25. The gated channel of claim 24, wherein the electronic states of the channel material is metal-insulator transition, superconducting transition, topological orders, or magnetic phases.

26. A transistor comprising:
a drain;
a source;
a channel disposed between the drain and the source, the channel being formed of channel material; and
a gate being formed of Pt electrode and the redox gating material of any one of the preceding claims disposed in the channel, wherein upon the cycling a gate voltage of about ±0.2 V to about ±1.5 V.

27. The transistor of any one of the preceding claims, wherein the channel material comprises a functional oxide or low-dimensional material.

28. The transistor of claim 27, wherein the functional oxide comprises one or more of WO₃, VO₂, LaNiO₃, NdNiO₃, Nd₁₋ₓSrₓNiO₂, and Pr₁₋ₓSrₓNiO₂.

29. The transistor of claim 27, wherein the low-dimensional materials comprises one or more of bismuth, MoS₂, HfS₂, and WSe₂.

30. A method of redox gating, comprising:
applying a gate voltage of about ±0.2 V to about ±1.5 V to a channel material gated with a gating material comprising a redox agent.

31. The method of claim 30, wherein the redox gating material comprises an admixture of transition metal salts or redox agents with one or more ionic electrolytes.

32. The method of claim 30 or 31, wherein the redox gating material has a redox potential of about −1V to about 1V.

33. The method of any one of claims 30 to 32, wherein the one or more redox agent comprise one or more of the transition metal salts with variable valency.

34. The method of claim 33, wherein the one or more transition metal salts with variable valency comprises one or more of Cu ions, Fe ions, V ions, Co ions, Ni ions, and their corresponding coordination ions.

35. The method of any one of claims 30 to 34, wherein the one or more redox agents comprise one or more redox-active functional groups.

36. The method of claim 35, wherein the one or more redox-active functional group is selected from the group consisting of ferrocene, viologen, quinone, TEMPO, thiophene, benzophenone, ferrocyanide, ferricyanide, and combinations thereof.

37. The method of claim 35 or 36, wherein the redox agent comprises one or more of poly(ionic liquids) comprising the one or more redox-active functional groups and ionic liquid species in monomer repeating units, connected through a polymeric backbone to form a macromolecular architecture.

38. The method of claim 37, wherein the ionic liquid species comprises one or more of quaternary imidazolines, quaternary pyridines, ferrocenium, cobaltocenium, ferrocyanide, ferrocyanide, dicyanamide, bis(trifluoromethylsulfonyl)imide, and hexafluorophosphate.

39. The method of claim 37 or 38, wherein the one or more poly(ionic liquid) comprises one or both of a conjugated poly(ionic liquid) and a metal-containing poly(ionic liquid).

40. The method of claim 39, wherein the conjugated poly(ionic liquid) comprises one or more of polythiophene poly(ionic liquid), poly(quinone) poly(ionic liquid), and poly(viologen) poly(ionic liquid).

41. The method of claim 40, wherein the polythiophene poly(ionic liquid) comprises one or both of 3,4-ethylenedioxythiophene and imidazole-functionalized thiophene monomers.

42. The method of claim 40, wherein the poly(quinone) poly(ionic liquid) comprises repeating quinone isomers.

43. The method of claim 42, wherein the repeating quinone isomers comprises one or more of benzoquinones, naphthoquinones, anthraquinone, and phenanthraquinones.

44. The method of claim 40, wherein the poly(viologen) poly(ionic liquid) comprises one or both of conjugated bi-/multi-pyridyl groups and 1,1′-disubstituted-4,4′-bipyridiliums.

45. The method of claim 39, wherein the metal-containing poly(ionic liquid) comprises one or more of ferrocene-containing poly(ionic liquids), ferrocyanide-containing poly(ionic liquids), and ferricyanide-containing poly(ionic liquids).

46. The method of claim 45, wherein ferrocene-containing poly(ionic liquids) comprises one or more of ferrocenylenes, ferrocenylsilanes, and pendant ferrocenes.

47. The method of any one of claims 30 to 46, wherein the transition metal salt is present in an amount below the saturated concentration in electrolyte solutions

48. The method of any one of claims 37 to 46, wherein the redox gating material is a liquid solution, and the poly(ionic liquid) is present in the redox gating material in an amount of about 1 wt % to about 15 wt % based on the total weight of the redox gating material.

49. The method of any one of claims 37 to 46, wherein the redox gating materials is an ionogel and the poly(ionic liquid) is a redox-active polymer present in an amount of at least about 15 wt % based on the total weight of the redox gating material.

50. The method of any one of claims 30 to 49, wherein the redox agent comprises a redox-active functional group, and the one or more redox-active functional groups are present in an amount of at least about 5% by mole of the redox-active functional groups based on the total mole of the redox gating material.

51. The method of any one of claims 30 to 50, wherein the ionic electrolyte is one or more of ionic liquids.

52. The method of claim 51, wherein the ionic liquid comprises one or more of:
1-ethyl-3-methylimidazolium dicyanamide (EMIM-DCA),
1-Butyl-3-methylimidazolium dicyanamide (BMIM-DCA),
1-ethyl-3-methylimidazolium bis(trifluoromethylsulfonyl)imide (EMIM-TFSI), and
diethylmethyl(2-methoxyethyl)ammonium bis(trifluoromethylsulfonyl)imide (DEME-TFSI).

53. The method of any one of claims 30 to 52, wherein the channel material comprises one or more of WO₃, VO₂, LaNiO₃, NdNiO₃, Nd₁₋ₓSrₓNiO₂, Pr₁₋ₓSrₓNiO₂, bismuth, MoS₂, HfS₂, WSe₂.
